(19) United States
(12) Patent Application Publication
(10) Pub. No.: US 2023/0065460 A1
(43) Pub. Date: Mar. 2, 2023

(54) HOUSING SYSTEM

(71) Applicant: Weidmüller Interface GmbH & Co. KG, Detmold (DE)

(72) Inventors: Matthias NIGGEMANN, Dörentrup (DE); Marco WALDHOFF, Steinheim (DE); Cedric BECKMANN, Horn-Bad Meinberg (DE); Benjamin WIND, Detmold (DE); Annekathrin BANCK, Bielefeld (DE)

(21) Appl. No.: 17/821,621

(22) Filed: Aug. 23, 2022

(30) Foreign Application Priority Data
Aug. 26, 2021 (DE) 202021104596.5

(51) Int. Cl. H05K 5/00

(52) U.S. Cl. CPC H05K 5/0013

(57) ABSTRACT

A housing system for electrical and electronic components, in particular for single-board computers and accessories includes a housing with side walls and slide-in walls and with at least one cover. The housing includes at least one basic frame with the side walls and with at least one corner pillar, wherein the at least one corner pillar forms interfaces for external mounts and internal mounts.

This application claims priority of DE 20 2021 104596.5 filed Aug. 26, 2021. The entire content of this application is incorporated herein by reference.

### BACKGROUND OF THE INVENTION

The present invention relates to a housing system for electrical and electronic components, in particular for single-board computers and accessories.

### BRIEF DESCRIPTION OF THE PRIOR ART

A wide variety of designs of such housing systems and housings are known. Electrical components are currently conventionally constructed on printed circuit boards of various kinds and are connected to different structural elements for terminal points such as clamps, switches, displays, actuators, which are attached into and/or onto the housing for the supply of power, operation, etc. in order to achieve as compact a construction as possible.

The housing protects the components from external influences but also at the same time prevents contact with parts of the components which have high electrical voltage and high temperature. A housing system includes all mechanical parts for the construction of the housing and offers possibilities for expansion. This is of particular importance in experimental construction, in the trial stage of electrical and electronic circuits, since changes of these are frequently performed with appropriate accessing by opening the housing.

An example of a housing for receiving an electrical or electronic functional component is illustrated by document WO 2018/172 363 A1.

The known solutions have proven their worth, in principle. However, there is a constant need for further development, with greater functionality being created alongside increased safety, compact construction and a smaller number of component parts.

The aim of the invention is to solve this problem.

### SUMMARY OF THE INVENTION

A housing system according to the invention for electrical and electronic components, in particular for single-board computers and accessories, includes a housing and side walls and slide-in walls and with at least one cover. The housing includes at least one basic frame with the side walls and with at least one corner pillar, wherein the at least one corner pillar forms interfaces for external mounts and internal mounts.

The housing system according to the invention is particularly suitable for single-board computers which offer a number of possible applications. These applications are, for example multimedia players, media servers, building automation, control and web servers for 3D printers, various automation tasks, IoT servers as cloud, test software and a number of trial structures.

In order to meet these requirements, the housing system according to the invention has universal interfaces for internal mounts and external mounts for various accessories.

The internal mounts advantageously enable a fast and simple insertion of accessories, e.g. expansions, fans, coolers etc. into the interior space, with the external mounts offering securing possibilities for the housing at various positions. At the same time, the external mounts also provide simple and quick mounting of, for example, cameras, sensors, operating devices, etc.

In one design, the at least one basic frame has four corner pillars which are firmly connected to side walls. Thus, the basic structure of the housing, which is expandable, is formed.

For this purpose, the housing can have at least one supplementary frame with at least one corner pillar, as a result of which a simple expansion construction is made possible.

It is advantageous if the at least one supplementary frame has four corner pillars, two corner pillars of which in each case are firmly connected to side walls, since in this manner there emerges a compact and easy alterable construction in which slide-in walls of different sizes can be used or also not inserted or quickly removed for better access to the interior space.

In one embodiment, the at least one corner pillar has an outer jacket in the form of a partially hollow cylinder with a three-quarter circular cross-section, wherein the outer jacket of the at least one corner pillar is the interface for external mounts. This is advantageous, since, as a result of this construction, on the one hand, weight saving is achieved and on the other hand, a compact construction is possible.

In a further embodiment, the housing system furthermore has at least one external mount, wherein the at least one external mount has at least one clamping section having a semicircular cross-section, the internal radius of which corresponds to the external radius of the outer jacket as an interface for external mounts of the at least one corner pillar. Thus, the corner pillars are advantageously suitable for the simple and quick attachment, changing and releasing of external mounts with appropriate clamping devices. In this case, it is particularly advantageous that no tool is required for such changes.

In another embodiment, one inner pillar with a central through-opening is arranged in the outer jacket of the at least one corner pillar. This provides savings in terms of space and weight.

If the through-opening of the inner pillar is configured as an internally hexagonal cross-section, it is possible to employ standard screwing with hexagonal screws and nuts.

In another embodiment, a channel wall which extends along the inner pillar and has a channel is arranged on the inner pillar. This construction offers advantageous stability and additional space at the corner pillar, e.g. for further closure mechanisms of the housing.

According to a further embodiment, on each side of the channel wall, a holding section is defined by a prolongation of the side wall attached to the corner pillar, the channel wall and a bar attached to the side wall, wherein these two holding sections form an insert receptacle as an interface for internal mounts. The corner pillars thus have further functionality along with compact construction.

According to yet another embodiment, the insert receptacle has a bar which is secured in the longitudinal direction of the channel wall and which forms a separation of the two holding sections in the longitudinal direction. This advantageously enables greater stability of the corner pillar.

If the two holding sections are divided in a transverse direction by a crossbar and form two insert receptacles, wherein the insert receptacles are each opened towards an interior space of the associated frame, wherein in each case the opening is defined by the bars, the bar and the crossbar, and wherein the insert receptacle forms the interface for internal mounts of the at least one corner pillar, the interfaces can form simple fixing of the internal mount which is to be employed.

Yet another embodiment, the housing system furthermore has at least one internal mount, wherein the at least one internal mount has a holding device, the shape of which, for form-fitting engagement, corresponds to the shape of the insert receptacle as an interface for internal mounts of the at least one corner pillar. Particularly simple and fast mounting can thus be made possible.

The holding device can have bar-shaped protrusions or/and prestressed spring bars which set the holding device in the holding sections in a form-fitting manner and in a force-fitting manner by friction. This is advantageous for a simple and compact assembly.

The housing can be held together by securing elements, preferably screws and nuts, which are arranged in the through-opening of the inner pillar of the at least one corner pillar.

For simple and quick assembly, the housing can be held together by magnets, which, as permanent magnets, form magnetic closures. In this manner, the housing can obviously also be opened and closed simply and quickly. This is of great advantage in the case of trial structures and expansions.

The magnets of the magnetic closures are arranged in the entrances to the through-opening of the inner pillar of the at least one corner pillar and in receptacles in the covers. This is particularly advantageous since it provides a compact construction. The magnets can be glued in or/and clamped in.

The covers preferably have pillar caps which enclose the corner pillars. Thus, a compact construction is achieved with the internal mounts arranged in the holding sections of the corner pillars additionally also being fixed at the same time.

The following advantages of the invention are provided:
possibilities for enlarging the housing via supplementary frames for larger structures (fans, additional boards, plugged additional boards, power packs)
holding of bearing rails
internal clamping strips
plug-in connector (e.g. for operating units, sensors, actuators)
closed housing (plastic, metal or combinations)
freely accessible connections (e.g. via slide-in walls)
compact, robust and slim housing
reception of experimental boards
connections on various sides, top, bottom
low costs
various types of IP-protection possible (e.g. IP34)
simple mounting and removal
integrated mountings (e.g. for camera, display, operating unit, etc.)
cable openings and cable bundling

### BRIEF DESCRIPTION OF THE DRAWING

Exemplary embodiments of the invention will be described below with the aid of the accompanying drawings. These exemplary embodiments serve only to illustrate the invention using preferred constructions which, however, do not, definitively depict the invention. In this regard, other exemplary embodiments, modifications and equivalents of the exemplary embodiments depicted can also be realized. In the drawings:

FIG. 1 is a perspective view of an exemplary embodiment of a housing according to the invention;

FIG. 2 is a perspective inner view of the housing according to FIG. 1;

FIG. 3 is an enlarged perspective inner view of use areas of a corner pillar on the inside of the housing;

FIG. 4 is a perspective view of a second exemplary embodiment of the inventive housing according to FIG. 1;

FIG. 5 is an exploded view of the second exemplary embodiment of the inventive housing according to FIG. 4;

FIG. 6 is a sectional view of the corner pillars of the second exemplary embodiment according to FIG. 4;

FIGS. 7 and 8 are perspective views of the second exemplary embodiment according to FIG. 4 with external accessory holders, respectively;

FIGS. 9 and 10 are perspective views of external accessory holders according to FIGS. 7 and 8, respectively;

FIGS. 11 and 12 are perspective internal views of corner columns with external accessory holders, respectively;

FIGS. 13, 14, 15, and 16 are perspective views of internal accessory holders, respectively; and

FIG. 17 is a sectional view of a modified version of the housing.

### DETAILED DESCRIPTION

The terms “top”, “bottom”, “left” and “right” relate to the respective arrangement of the component parts in the figures.

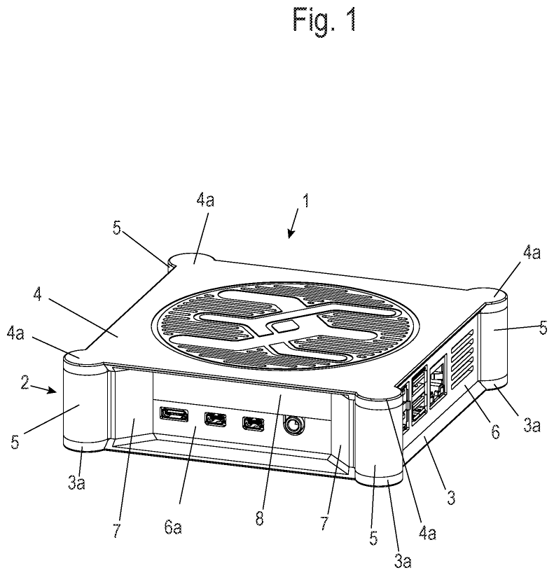

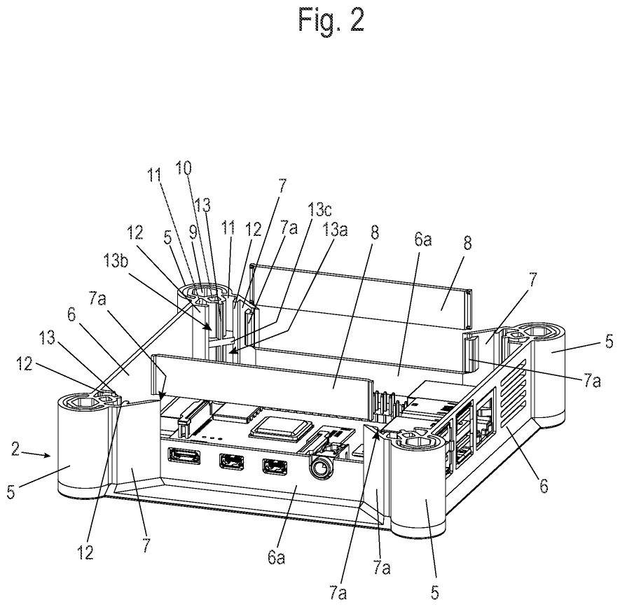

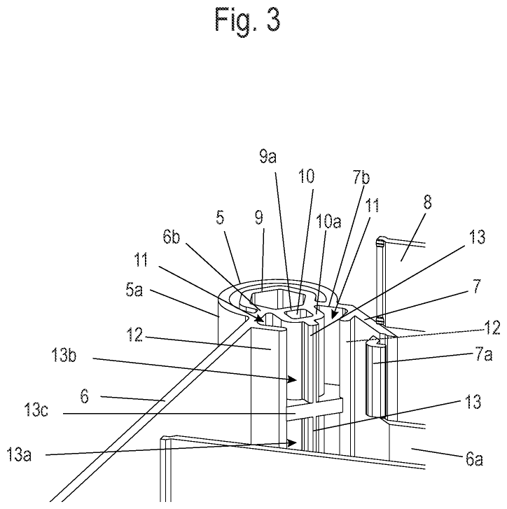

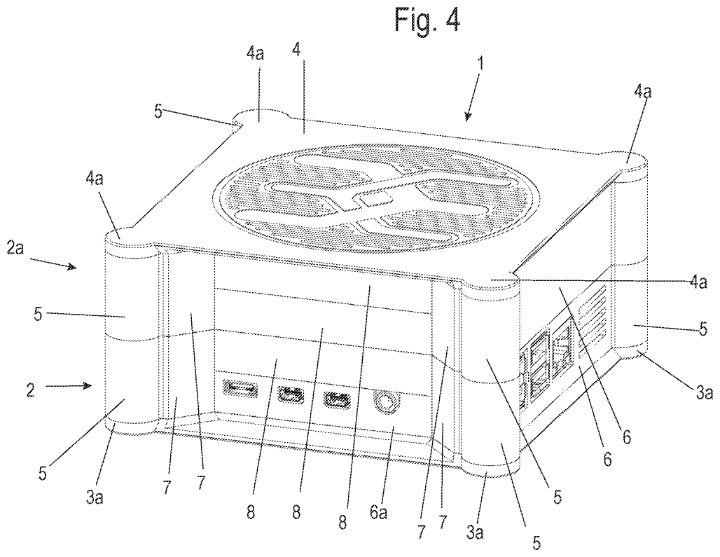

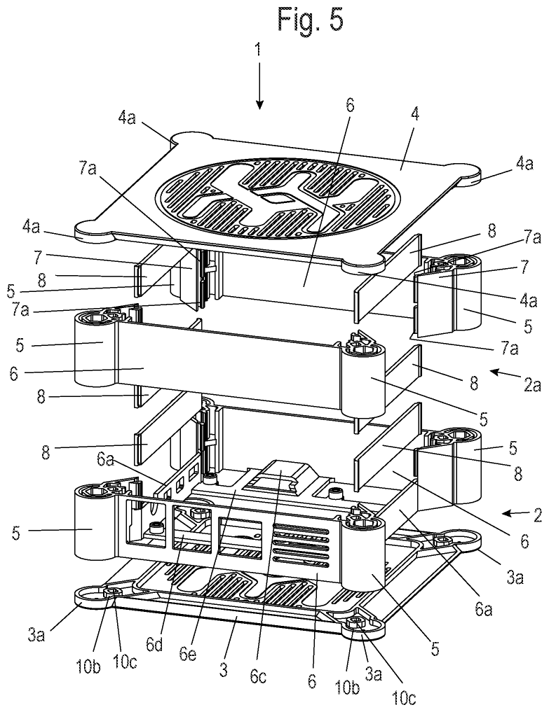

FIG. 1 depicts a perspective view of an exemplary embodiment of a housing 1 according to the invention. In addition, FIG. 2 is perspective internal view of the housing 1 according to FIG. 1. FIG. 3 is an enlarged perspective view of insert receptacles 13a, 13b of a corner pillar 5 on the inner side of the housing 1 according to FIG. 1. FIG. 4 is a perspective view of a second exemplary embodiment of the inventive housing 1 according to FIG. 1. FIG. 5 is an exploded view of the second exemplary embodiment of the inventive housing 1 according to FIG. 4.

The housing 1 receives one or more single-board computers (SBC) with electrical supply units (e.g. a power pack, battery etc.), fans, connections for keyboards, printers, sensors, actuators etc. e.g. by plug-in connectors and the like, additional boards and so on.

The housing 1 of the first embodiment includes a basic frame 2, a bottom cover 3, a top cover 4, fixed side walls 6, 6a and slide-in walls 8. When the housing 1 is being used for certain purposes, the slide-in walls 8 can be omitted or removed in order to gain access to installed parts/systems.

The slide-in walls can be installed or removed mechanically by the customer. Therefore, for example, additional bores or/and recesses for connections, cable entry points, displays and the like can be introduced.

The housing 1 is part of a housing system, which additionally includes internal mounts and external mounts, as well as securing elements, connection screws, etc.

In one example, a base area of the housing 1 is dimensioned such that printed circuit boards in the European card format of 100 mm×160 mm can be installed.

In one design, the housing 1 is square, for example.

The shape of the housing 1 is rectangular, with at least one corner of the housing 1 configured as a corner pillar 5. In the example shown, each corner is provided with a corner pillar 5. The basic frame 2 is constructed such that the corner pillars 5 are connected to one another by the fixed side walls 6, 6a. In this case, two fixed side walls 6, which correspond to the height of the corner pillars 5, are situated opposite each other.

The fixed side walls 6a, at half the height of the corner pillars 5, are likewise arranged opposite one another, but offset in the direction of the interior of the basic frame 2 and are connected to the associated corner pillars 5 on each side respectively via short holding walls 7. For this purpose, the holding walls 7 run at an angle, from an imaginary straight line connecting the corner pillars 5, to the interior of the basic frame 2.

Above the side walls 6a, one slide-in wall 8 in each case is inserted between the holding walls 7. The slide-in walls 8 are pushed by their sides into holding brackets 7a on the inner sides of the holding walls 7 and are held by these. This is illustrated in FIG. 2.

Different connections, e.g. HDMI, USB, jack plug connections, are arranged in the fixed side wall 6a which is shown in the foreground in FIG. 1. Additionally, another one of the side walls 6, on the right side in FIG. 1, is equipped with various connections. These connections can be situated on a printed circuit board in the interior of the housing 1, with matching breakthroughs formed in the side wall 6, 6a. The connections can also be installed as separate plug-in connections in the relevant side wall 6, 6a, which has matching openings.

The basic frame 2 is enclosed on its underside by the bottom cover 3. The cover 4 is fitted onto the upper side of the basic frame 2. Both the bottom cover 3 and the top cover 4 enclose the upper side and underside of the corner pillars 5 with pillar caps 3a, 4a which match the shape of the corner pillars 5. The pillar caps 3a, 4a are configured integrally with the respective cover 3, 4 here.

The construction of the corner pillars 5 is identical. They each have an outer jacket 5a in the form of a partially hollow cylinder with a three-quarter circular cross-section. One of the side walls 6, 6a, or rather holding walls 7, is in each case attached to each side of this outer jacket 5a.

The corner pillar 5 construction described below applies to all corner pillars 5. This construction is clearly depicted in the enlarged view in FIG. 3.

An inner pillar 9 is arranged in the outer jacket 5a concentrically to the partially hollow cylinder. The inner pillar 9 has a hexagonal external cross-section and a central through-opening in the direction of the longitudinal axis of the inner pillar. This through-opening is configured as an internal hexagonal cross-section.

The inner pillar 9 is arranged such that a flat segment 9a extending in the direction of the hollow cylinder axis is arranged between the ends of the outer jacket 5a of the corner pillar 5 and a surface normal to this flat segment 9a runs in the direction of a diagonal or imaginary line connecting the midpoints of the corner pillar 5 situated diagonally opposite.

A channel 10 in a channel wall 10a, which channel extends in the longitudinal direction of the inner pillar 9, is arranged at the flat segment 9a of the inner pillar 9. The channel 10 is defined by the channel wall 10a surrounding it and by the flat segment 9a of the inner pillar 9. Here, the channel 10 has a quadrangular, in particular square, cross-section configuration and is continuous.

A bar 13 extending in the longitudinal direction of the channel wall 10a is formed onto the section of the channel wall 10a that runs parallel to the flat segment 9a.

The bar 13 protrudes from the channel wall 10a in the direction of the aforementioned diagonals and surface normals. The bar 13 runs on the channel wall 10a over the entire length or height of the corner pillar 5 and is connected to a crossbar 13c at half of its length.

The inner pillar 9 is additionally connected in the opening between the ends of the outer jacket 5a to these two ends via one lateral prolongation 6b, 7b of the side wall 6 and the holding wall 7 in each case.

Opposite the two sides of the channel wall 10a, which are attached to the flat segment 9a of the inner pillar 9 at right angles to it, bar 12 is arranged in each case at an inner side of the side wall 6 and the holding wall 7. These bars 12 protrude from the inner side of the walls 6 and 7, inclined by a certain angle to the respective wall 6, 7, into the interior space of the basic frame 2. In a respective imaginary prolongation of these bars 2 into the interior space of the basic frame 2, these imaginary prolongations intersect at an angle of 90°.

The crossbar 13c is connected to the edges of the bars 12. A length of the bars 12 corresponds to a length of the associated corner pillar 5.

In this manner, a holding section 11 is defined by the prolongation 6b, 7b, the channel wall 10a and the bar 12 on each side of the channel wall 10a. These two holding sections 11 are symmetrical to one another along an axis of symmetry of the bar 13. The bar 13 forms a separation of these two holding sections 11 in the longitudinal direction. Both holding sections 11 are upwardly and downwardly open in their longitudinal direction.

A crossbar 13c divides these two semi-sections 11 into two upper and two lower semi-sections 11. The two upper holding sections 11 form an upper insert receptacle 13b. Below the crossbar 13c, the two lower holding sections 11 form a lower insert receptacle 13a.

The insert receptacles 13a and 13b are each opened towards the interior space of the basic frame 2, with the respective opening being defined by the bars 12, the bar 13 and the crossbar 13c.

It is also possible to omit crossbar 13c. In this case, the insert receptacles 13a and 13b form a common insert receptacle. This is not shown but is easy to understand.

The insert receptacles 13a, 13b are configured at each corner pillar 5. They form an interface for internal mounts or accessory holders, which will be described further below.

In the second embodiment according to FIG. 4, the housing 1 includes the basic frame 2 and a supplementary frame 2a with fixed side walls 6 and slide-in walls 8. In a further configuration, the housing 1 can obviously also have more than one supplementary frame 2a.

The supplementary frame 2a is fitted onto the basic frame 2 such that the corner pillars 5 of the supplementary frames 2a and of the basic frame 2 are arranged coaxially above one another.

The supplementary frame 2a differs here from the basic frame 2 in that it has only two fixed side walls 6, which are arranged opposite one another. The other sides in this example have two insert walls 8 situated one above the other. The insert walls 8 are connected to the holding walls 7 as described in the first embodiment. Thus, the supplementary frame 2a, in contrast to the basic frame 2, includes two fixed side walls 6 which are each firmly connected to two corner pillars 5.

FIG. 5 depicts the bottom cover 3, seen from its inner side. An SD card shaft on a printed circuit board arranged in the interior of the housing 1 can be accessible, for example after removing the bottom cover 3 or the top cover 4. In this case, a trough 6c can be provided under the card shaft, which prevents an SD card from falling into the housing 1.

The trough 6c is arranged on a plate element 6d, which is secured between the fixed side walls 6a in front of the fixed side wall 6, which is situated to the rear in FIG. 5, in a manner which is not described in greater detail. A further plate element 6e is arranged parallel to the fixed side wall 6 which is at the front in the image. Screw bosses for screwing-on accessories and printed circuit boards are arranged on these plate elements 6d, 6e. Such screw bosses can obviously also be attached to the side walls 6, 6a, slide-in walls 8 or/and covers 3, 4.

In the region of the pillar caps 3a, receptacles 10c corresponding to the shape of the channel 10 and the channel wall 10a are formed onto them. The receptacles 10c will be described in greater detail further below.

The basic frame 2 and supplementary frame 2a can be connected to one another by screwing into the corner pillars. There are various fixations for the bottom cover 3 and the cover 4 which are possible individually or in combination.

Magnetic closures are a possibility for fast assembly and at the same time firmly hold the basic frame 2, supplementary frame 2a, bottom cover 3 and cover 4 of the housing 1. These are also simple to remove.

The bottom cover 3 and/or top cover 4 can also be screwed onto the frame 2, 2a. For this purpose, conventional screws and/or fast closure elements, such as bayonet connections, for example, can be used.

In a different manner which is not shown but easy to imagine, the bottom cover 3 and/or the cover 4 can be designed to be clamped on. They are then also relatively easy to take off and to mount again.

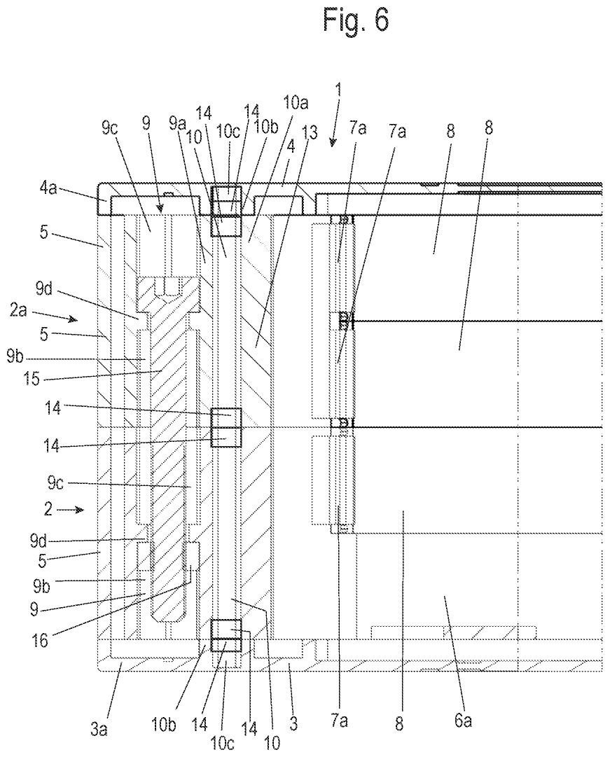

Exemplary types of connection will now be described in conjunction with FIG. 6.

In this regard, FIG. 6 shows a schematic sectional view of corner pillars 5 of the second embodiment of the housing 1 according to FIG. 4 with a fixed side wall 6 and three insert walls 8.

FIG. 6 depicts both screwing-together and magnetic closures which can be used individually in isolation or together. For example, a screwing together of the basic frame 2 and the supplementary frame 2b can be provided, with the bottom cover 3 and the cover 4 being provided with magnetic closures.

The through-openings of each inner pillar 9 each have two inner pillar sections 9b and 9c, which are divided by means of a collar 9d into two inner pillar sections 9b, 9c of equal size. The collar 9d is provided as a ring with a through-bore.

Securing elements 15 and 16, configured as a screw with a hexagonal head and a hexagonal nut, are arranged in the inner pillars 9. The screw extends through the through-bores of the collar 9d of the upper corner pillar 5 of the supplementary frame 2a and of the collar 9d of the lower corner pillar 5 of the basic frame 2. The dimensions of the hexagonal head of the screw and the hexagonal nut correspond to the dimensions of the inner hexagon of the inner pillar 9. The screw head rests on the collar 9d of the inner pillar 9 of the supplementary frame 2a as an abutment. The lower collar 9d of the inner pillar 9 of the basic frame 2 serves as an abutment for the hexagonal nut. The hexagonal nut, during mounting, is first pushed into the lower inner pillar section 9b of the corner pillar 5 of the basic frame 2. By turning the screw, the hexagonal nut enters engagement with the thread of the screw and then, when the screw is turned further, is tightened against the lower collar 9d of the inner pillar 9 of the lower corner pillar 5 of the basic frame 2. The internal hexagonal cross-section of the inner pillar sections 9b, 9c forms an anti-rotation lock on the hexagonal screw and the hexagonal nut during screwing-together and releasing.

The screw connections of the other corner pillars 5 of the housing 1 are manufactured in this manner too.

In an alternative, which is not shown, two screws and a long nut may be used. The long nut is arranged in the lower inner pillar section 9b of the upper inner pillar 9 of the corner pillar 5 of the supplementary frame 2a and in the upper inner pillar section 9c of the lower inner pillar 9 of the corner pillar 5 of the basic frame 2. A first screw is screwed into the long nut from above through the upper inner pillar section 9c of the upper inner pillar 9 through the collar 9d. A second screw is screwed into the long nut from below through the lower inner pillar section 9b of the lower inner pillar 9 through the collar 9d. This is not shown but, viewed together with FIG. 6, is easy to imagine.

A further, unshown alternative uses only a long screw and nut as securing elements 15, 16. The screw extends through unshown, but easily imaginable bores in the pillar caps 4a and 3a of the covers 3, 4 and the collars 9d. The pillar caps 4a and 3a thereby form the abutment for the screw and nut. Washers may be arranged between the screw head and cover 4 or nut and bottom cover 3 (or vice versa). In this further alternative, hexagonal screws are not absolutely necessary.

The magnetic closures have magnets 14 as permanent magnets, e.g. neodymium magnets. To secure the bottom cover 3, a magnet 14 is secured in the lower opening of the channel 10 of the basic frame 2. A further magnet 14 of this magnetic closure is situated in the receptacle 10c of the channel cap 10b in the pillar cap 3a of the bottom cover 3. In this manner, four magnetic closures for the bottom cover 3 are arranged.

The magnets 14 are firmly glued or clamped in their positions, for example. A spacer, e.g. in the form of a rod or the like, may also be arranged between the magnets 14 in the channel 10. Instead of a continuous channel 10, there can also only be molded one opening, which fits the magnets 14 in each case at the channel entrances. This can, however, increase the total weight of the housing 1 and the price of materials.

Of course, the corner pillar 5 can also be made of solid material in which the through-opening with the internally hexagonal cross-section and the channel 10 are molded. This unshown but imaginable design is also conceivable, but this increases a total weight of the housing 1 and the price of materials.

In the closed state, the bottom cover 3 rests on the underside of the basic frame 2 such that the magnets 14 mutually attract one another and offer a fast connection during assembly, which connection forms a relatively firm connection depending on the strength of the magnets 14.

The magnetic closures of the cover 4 are likewise formed in this manner.

The magnetic closures are designed similarly between the basic frame 2 and the supplementary frame 2a. One magnet 14 in each case is secured in the lower opening of the channel 10 of the supplementary frame 2a and in the upper opening of the channel 10 of the basic frame 2. Four of these magnetic closures enable the basic frame 2 and the supplementary frame 2a to be firmly held together when the housing 1 is in the assembled state.

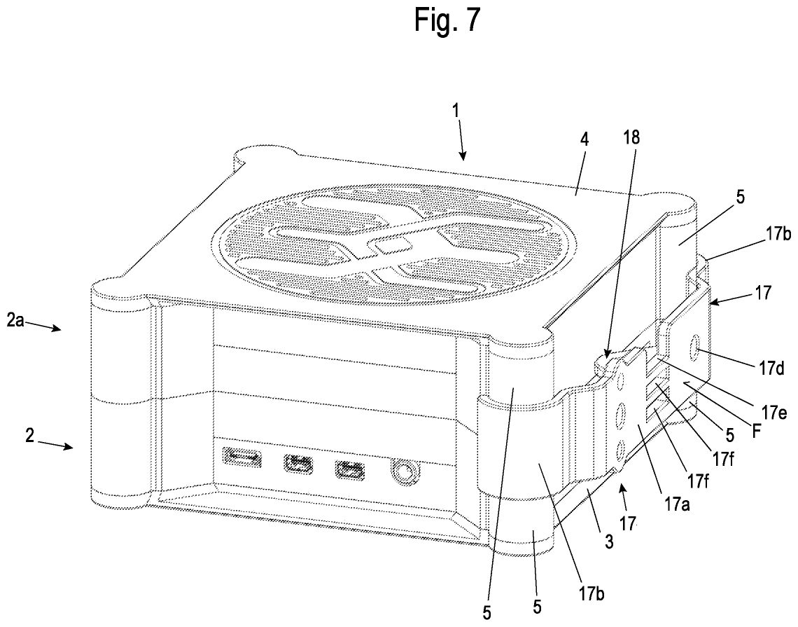

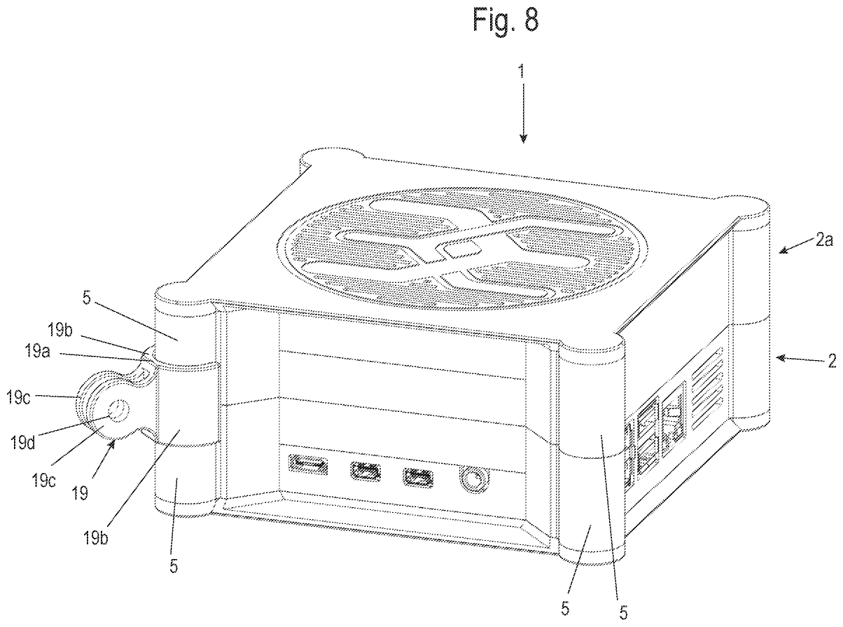

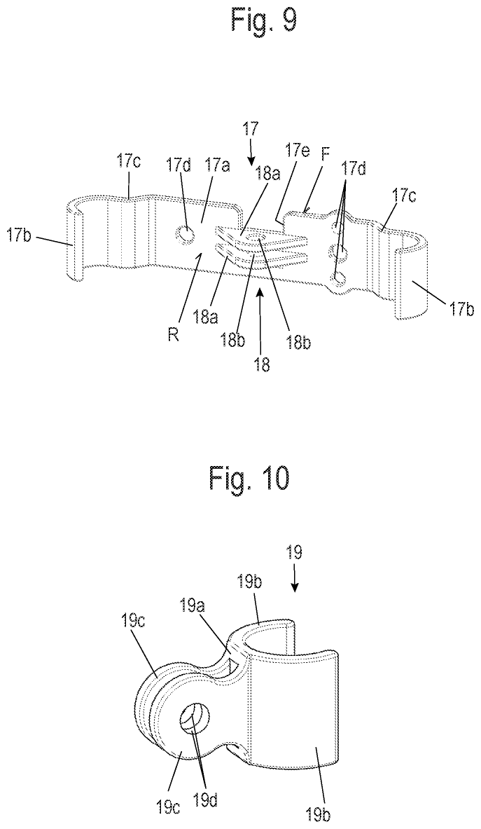

FIGS. 7-8 are perspective views of the second exemplary embodiment according to FIG. 4 with external accessory holders. FIG. 7 is perspective view of the second exemplary embodiment of the housing 1 according to FIG. 4 with a securing bracket 17 for securing the housing 1 at various locations. FIG. 8 depicts the housing 1 with a holder 19 for securing accessories to the housing 1. FIG. 9 shows a perspective view of the external accessory holder securing bracket 17 according to FIGS. 6-7. FIG. 10 depicts a schematic perspective view of the external accessory holder 19.

The securing bracket 17 makes it possible to secure the housing 1 at various locations both only with the basic frame 2 and also with the basic frame 2 and the supplementary frame 2a, as shown in FIG. 7.

The securing bracket 17 can be attached to the housing 1 in a simple manner. No tool is required. Likewise, simple removal of the securing bracket 17 is possible.

For this purpose, the securing bracket 17 includes a base plate 17a, two clamping sections 17b and a mount 18.

The base plate 17a is substantially a rectangular plate, at each end of which a clamping section 17b is attached resiliently via a respective connection 17c which may be crimped. The clamping sections 17b have a semicircular cross-section, the internal radius of which corresponds to the external radius of the corner pillars 5. The clamping sections 17b are arranged symmetrical to one another, with their short side edges being curved towards one another in the direction of a rear side R of the securing bracket 17.

By a rear side R, pointing towards the housing 1, the securing bracket 17 is clipped onto it via the clamping sections 17b at the corner pillars 5 of the housing 1. A front side F of the securing bracket 17 points outwards and forms a contact surface for parts to be secured to the base plate 17a, e.g. holding brackets, bearing rail mounts, etc. For this purpose, the base plate 17a is equipped with different through-openings 17d for holding screws, holding pins, etc.

A recess 17e is molded in a central region of the base plate 17. In this region, the mount 18 is attached to the rear side R of the base plate 17a. The mount 18 has two holding jaws 18a which are spaced apart parallel to one another, each with a through-opening 18b. The through-openings 18b are circular holes and are arranged coaxial to one another.

The recess 17e is arranged above the upper holding jaw 18a. One rectangular opening 17f in the base plate 17a in each case is molded between the upper holding jaw 18a and the lower holding jaw 18a situated below it, and under the lower holding jaw 18a. The recess 17e and the openings 17f allow the plugging-through of standardized mounts belonging to external accessories, such as a display, camera, switches, display lights, etc., which can be fixed to the mount 18 by means of appropriate latching parts or/and clamping/latching bolts with the aid of the through-openings 18b.

The clamping sections 17b are arranged spaced apart from one another on the base plate 17a of the securing bracket 17 such that their imaginary center lines correspond to the spacing of the imaginary center lines of the corner pillars 5 of the housing 1. A height of the securing bracket 17 corresponds to the height of the fixed side walls 6 of the basic frame 2.

The holder 19 for securing external accessories, e.g. standardized mounts for cameras, etc., comprises a base plate 19a, a clamping section 19b and holding jaws 19c with through-openings 19d.

The base plate 19a is rectangular and connected to the clamping section 19b. The clamping section 19b, like the clamping sections 17b of the securing bracket 17, has a semicircular cross-section, the internal radius of which corresponds to the external radius of the corner pillars 5.

The holding jaws 19c, similarly to the holding jaws 18a of the mount 18, are arranged spaced apart parallel to one another on an outer side of the base section 19a. The through-openings 19d are circular holes and are arranged coaxial to one another as well.

By means of the clamping section 19b, the holder 19 can be clamped, at any position, on the corner pillars 5 of the housing 1. No special tool is required for attaching or removing.

In other words, the corner pillars 5 form interfaces for the external mounts of external accessories, with the external mounts possibly being securing brackets 17 and mounts 18.

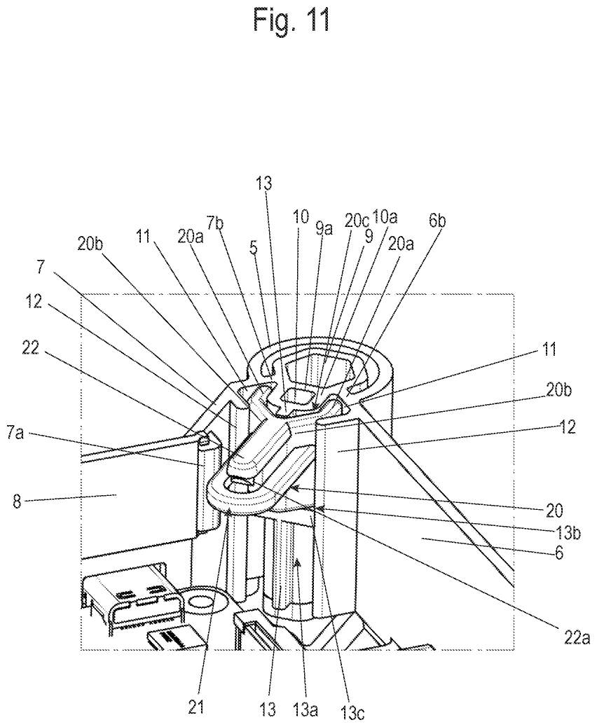

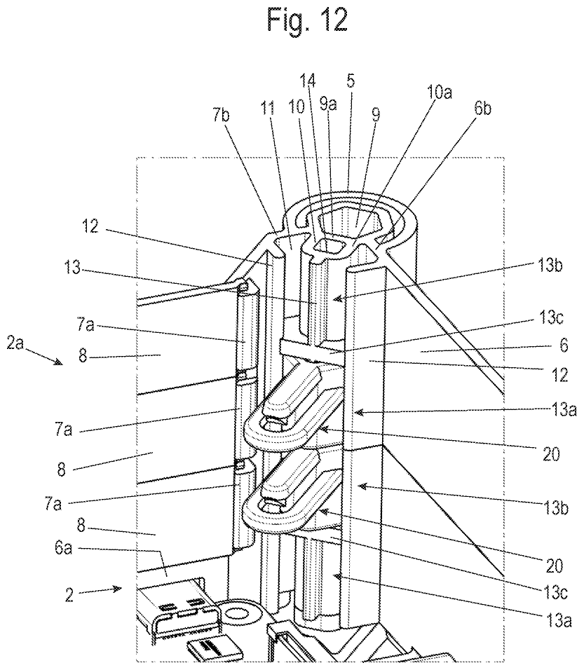

FIGS. 11 and 12 depict schematic perspective internal views of the corner pillars 5 with internal accessory holders.

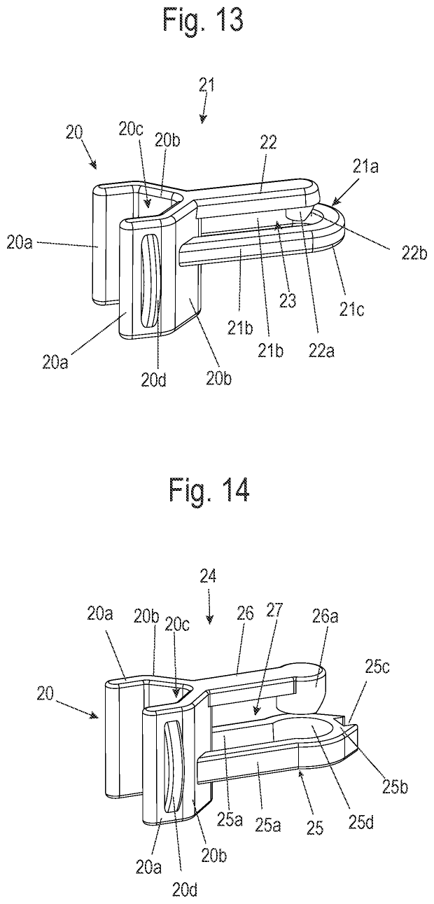

FIG. 11 shows an inner corner region of the basic frame 2 of the housing 1 with a corner pillar 5 and with a holding element 21. FIG. 12 depicts two holding elements 21 in the inner corner region, both in the basic frame 2 and in the supplementary frame 2a. FIG. 13 shows a schematic perspective view of the holding element 21.

The above-described insert receptacles 13a and 13b of the corner pillar 5 are depicted as enlarged. The lower insert receptacle 13a is free, and the holding element 21 is pushed in from above into the upper insert receptacle 13b. The holding element 21 has a holding device 20, the shape of which corresponds to the shape of the insert receptacle 13a, 13b for a form-fitting engagement.

The holding device 20 includes holding plates 20a, 20b, a receptacle 20c and bar-shaped protrusions 20d (see FIG. 13).

The holding plates 20a and the holding plates 20b are configured as rectangular plates. The holding plates 20a are arranged parallel to one another and have free, rounded-off corners.

One further holding plate 20b is attached at an angle to a respective longitudinal side of a holding plate 20a such that the free longitudinal sides of the holding plates 20b are connected to one another

The inner surfaces of the holding plates 20a and of the holding plates 20b form the receptacle 20c between them.

One bar-shaped protrusion 20d is arranged in each case on the outer surfaces of the holding plates 20a in the longitudinal direction. The bar-shaped protrusions 20d are secured at their ends to the respective holding plate 20a, with them each protruding, in this example, outwards as a semicircular piece from the respective outer surfaces of the holding plates 20a. The bar-shaped protrusions 20d can be configured in one piece with the holding plates 20a and can also be fully sprayed out in the case of an injection-molded part

In an embodiment which is not shown but which can be easily imagined, the bar-shaped protrusions 20d can be configured as resilient elements, e.g. as spring bars. It is also conceivable that both bar-shaped protrusions 20d and spring bars can be used.

This holding device 20 is identical for all internal mounts, which will be described further below. Different mounts are respectively attached to the holding device 20 as brackets, arms, clips, etc., which protrude from the holding device 20.

The holding device 20 and the insert receptacles 13a, 13b each form an interface for attaching of the different mounts. In this manner, all internal mounts can be universally inserted in the insert receptacle 13a, 13b in all possible positions inside the housing 1.

In the inserted state, the holding plates 20a of the holding device 20 in the insert receptacle 13a, 13b in the holding sections 11 thereof are each laterally received between the bar 12, the prolongation 6b, 7b and the channel wall 10a, laterally limited by the crossbar 13c at the top or bottom as the case may be. After sliding-in, the bar-shaped protrusions 20d on the holding plates 20a of the holding device 20 are in contact with the walls of the insert receptacle 13a, 13b. In this manner, the bar-shaped protrusions 20d fix the holding device in the holding sections in a force-fitting manner through friction and in a form-fitting manner through their shape. The bar-shaped protrusions 20d can also protrude with excess.

The holding plates 20b of the holding device 20 are each arranged between the bar 12 and the bar 13 of the insert receptacle 13a, 13b, with the channel walls 10a and the longitudinal bar 13 being arranged in the receptacle 20c of the holding device 20. The bar 13 contacts the connection of the longitudinal sides of the holding plates 20b of the holding device 20.

The holding element 21 or other mounts can be inserted or slid into the insert receptacle(s) 13a, 13b, if the housing 1 is opened. To do this, the associated covers 3, 4 must be removed. After insertion of the mount, the parts to be held by the mount(s) are slid, clamped, etc. into the mounts. If the housing 1 is closed again, the holding device 20 of the respective mount is axially fixed in the insert receptacle 13a, 13b by the pillar caps 3a, 4a of the covers 3, 4 and the crossbars 13c.

The holding element 21 includes the holding device 20, a bracket 21a and a spring arm 22. This is clearly depicted in FIG. 13.

The bracket 21a is configured in a U-shape and has two parallel bracket arms 21b and a semicircular connector 21c. The connector 21c connects the bracket arms 21b at their free ends. The other ends of the bracket arms 21b are attached to the outer sides of the inclined holding plates 20b of the holding device 20 in an upper-third of the holding plates 20b. The bracket 21a, by its U-shape, is in a plane at right angles to an imaginary longitudinal axis of the receptacle 20c of the holding device 20.

Above the bracket 21a, the spring arm 22, in an upper region, is attached to the connection of the inclined holding plates 20b of the holding device 20. An upper side of the spring arm 22 is flush with the upper side of the holding plates 20a, 20b of the holding device 20. A holding space 23 is formed between the underside of the spring arm 22 and the bracket 21a. The spring arm 22 is arranged in a plane parallel to the plane of the bracket 21a over the intermediate space formed by the bracket arms 21b of the bracket 21a. The free end of the spring arm 22 is rounded-off. A length of the spring arm 22 approximately corresponds to the length of the intermediate space between the bracket arms 21b.

On the underside of the free end of the spring arm 22, there is formed a protrusion 22a in the shape of a circular cylinder which protrudes downwards from the underside of the spring arm 22 and which is provided with a chamfer 22b on its front side which points toward the free end of the spring arm 22.

A spacing between the spring arm 22 and the bracket 21a corresponds to the thickness of a conventional printed circuit board or a holding surface of an object which is to be held. The protrusion 22a serves to fix the object to be held by virtue of the protrusion 22a being pushed upwards with the spring arm 22, due to the chamfer 22b, when the object is slid in between the bracket 21a and the protrusion 22a and latching into a mold in the object which is intended for the protrusion 22a. When the spring arm 22 is pushed up, it is stressed and pushes the protrusion 22a into the mold intended for it with a predetermined force.

In the positions of the inserted holding element 21 shown in FIGS. 11 and 12, the brackets 21a and the spring arms 22 protrude into the interior space in the direction of a diagonal of the interior space of the housing 1.

FIG. 12 also shows a magnet 14 in the upper opening of the channel 10.

FIG. 12 shows two holding elements 21 arranged over one another. The upper holding element 21 is received in the lower insert receptacle 13a of the corner pillar 5 of the supplementary frame 2a. The lower holding element 21 is situated in the upper insert receptacle 13b of the corner pillar of the basic frame 2.

The insert receptacles 13a, which are arranged on top of one another, of the supplementary frame 2a, and 13b of the basic frame 2 form a common insert receptacle 13a, 13b, which has twice as much space as an individual insert receptacle 13a, 13b. If only one of these common insert receptacles 13a, 13b is required, a corresponding insert, for example, can be inserted into the insert receptacle 13a, 13b which remains empty, in order to axially fix the individual holding element 21 in the other insert receptacle 13a, 13b (if the clamping force of the spring bars/bar-shaped protrusions 20d of the holding device 20 of the individual holding element 21 is not sufficient)

The internal mount shown in FIG. 14 forms a fan clip 24 for mounting a fan inside the housing 1, e.g., to cool electronic component parts.

The fan clip 24 includes the holding device 20, a U-shaped bracket 25 and a spring arm 26.

The bracket 25 is configured in a U-shape with two parallel bracket arms 25a and a semicircular connector 25b. In this bracket 25, in contrast to the bracket 21a of the holding element 21, the ends of the bracket arms 25a are formed together with the connector 25d like a ring with a three-quarter circular receptacle 25d.

At the front end of the connector 25d, there is molded a recess 25c, which serves the positioning of a fan (not shown) which is to be held.

The bracket arms 25a are attached to the outer sides of the inclined holding plates 20b of the holding device 20 in a lower third of the holding plates 20b. The bracket 25, by its U-shape, is in a plane at right angles to an imaginary longitudinal axis of the receptacle 20c of the holding device 20.

Above the bracket 25, the spring arm 26, in an upper region, is attached to the connection of the inclined holding plates 20b of the holding device 20. An upper side of the spring arm 26 is flush with the upper side of the holding plates 20a, 20b of the holding device 20. A holding space 27, which is wider here than the holding space 23 of the holding element 21, is formed between the underside of the spring arm 26 and the bracket 25. The spring arm 26 is in a plane parallel to the plane of the bracket 25 over the intermediate space formed by the bracket arms 25a of the bracket 25. The free end of the spring arm 26 is rounded off and bears a ball-type protrusion 26a on the underside. A length of the spring arm 26 approximately corresponds to the length of the intermediate space between the bracket arms 25a.

The spacing between the spring arm 26 and the bracket 25 is adapted to a holding surface of the fan which is to be held. The protrusion 26a serves to fix the fan. When the holding surface of the fans is slid between the bracket 25 and the protrusion 26a, due to a slightly beveled front side of the protrusion 26a, the protrusion 26a is pushed up together with the spring arm 26 and latches into a mold in the fan's holding surface for the protrusion 26a. When the spring arm 26 is pushed up, it is stressed and pushes the protrusion 26a into the mold intended for it with a predetermined force.

When the holding surface of the fan is slid in, the fan is positioned by a fitting section (not shown) of the holding surface of the fan engaging in the recess 25c of the bracket 25 in a form-fitting manner.

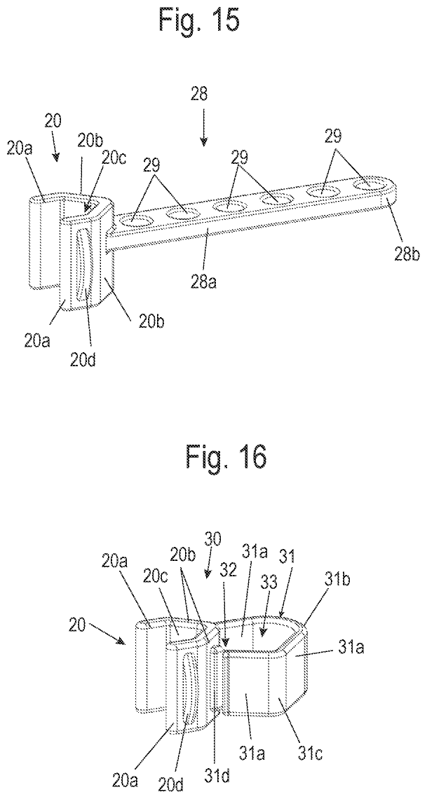

A further internal mount is shown in FIG. 15 in the form of a borehole clip 28.

The borehole clip 28 includes the holding device 20 and a holding arm 28a with boreholes 29.

The holding arm 28a has a rounded-off end section 28b at its free end. The holding arm 28a is fixed, in an upper third, to the outer sides of the inclined holding plates 20b of the holding device 20. The holding arm 28a is in a plane at right angles to an imaginary longitudinal axis of the receptacle 20c of the holding device 20.

In this example, the boreholes 29 are molded in the holding arm 28a as through-holes with the same diameter and at regular spacings. The boreholes 29 serve as universal securing holes for different accessories. The boreholes 29 can also serve as a hold for cable ties.

A cable clip 30 is depicted in FIG. 16 as an internal mount for electrical and/or optical wires/cables, etc.

The cable clip 30 includes the holding device 20 and a tie 31.

The tie 31 has a rectangular cross-section, the long side of which corresponds to approximately three-quarters of the long side of the holding plates 20b of the holding device 20.

In the example shown, the tie 31 includes three plate sections 31a and two curved sections 31b and 31c. These sections are connected to one another in an alternating order. Thus, one end of a first plate section 31a is secured to one of the inclined holding plates 20b of the holding device 20. At the other end, there is attached a first curved section 31b which has a large radius and which is connected to a second plate section 31a. For its part, the second plate section 31a is connected to a second curved section 31c which has a small radius. Finally, a third plate section 31a is secured to the second curved section 31c. One end of the third plate section 31a is, at a spacing 32, opposite a bar 31d which is attached to the other of the two holding plates 20b of the holding device 20.

In this manner, the tie 31 encloses, in a ring shape, a receiving space 33, through which cables and/or wires extend and are bundled and held by the tie 31. The tie 31 is configured to be resilient, with the receiving space 33 being able to be widened by increasing the spacing 32, since the third plate section 31a is not secured by its end to the bar 31d.

In the described examples, the housing 1 is manufactured from a suitable plastic. The housing 1 can be made partially or entirely from a transparent material. The external mounts 17, 19 and internal mounts 21, 24, 28, 30 are configured as one-piece plastic parts. Of course, all parts can be made of metal or from combinations of different materials, such as plastic and metal, for example.

The external mounts 17, 19 and internal mounts 21, 24, 28, 30 are not limited to the designs and quantities shown. Of course, they can be configured in an appropriately adapted manner for various use purposes.

Further not shown but easily imaginable designs of the basic frame 2 have, for example, only one corner pillar 5 or two or three corner pillars 5. In this case, the side walls 6, 6a are in each case connected to one another in the corners without corner pillars 5, with only one, only two or only three corners being equipped with a corner pillar 5. A respective appropriate supplementary frame 2a is also possible. The frames 2, 2a are connected, as described above, by securing elements 15, 16 in the corner pillar 5. Clamping elements are conceivable instead of the missing corner pillars 5. The magnetic closures can also be used in the corners without corner pillars 5, by attaching the magnets 14 in the wall corners to the side walls 6, e.g., by direct gluing-on or indirect gluing-on of small pockets in which the magnets 14 can be secured.

Of course, it is also possible to use slide-in walls 8 as described above.

The housing 1 can also include a basic frame 2 and several supplementary frames 2a. Likewise, two basic frames 2 can be used. Numerous combinations are possible, such as only supplementary frames 2a for example, i.e., a closed housing 1.

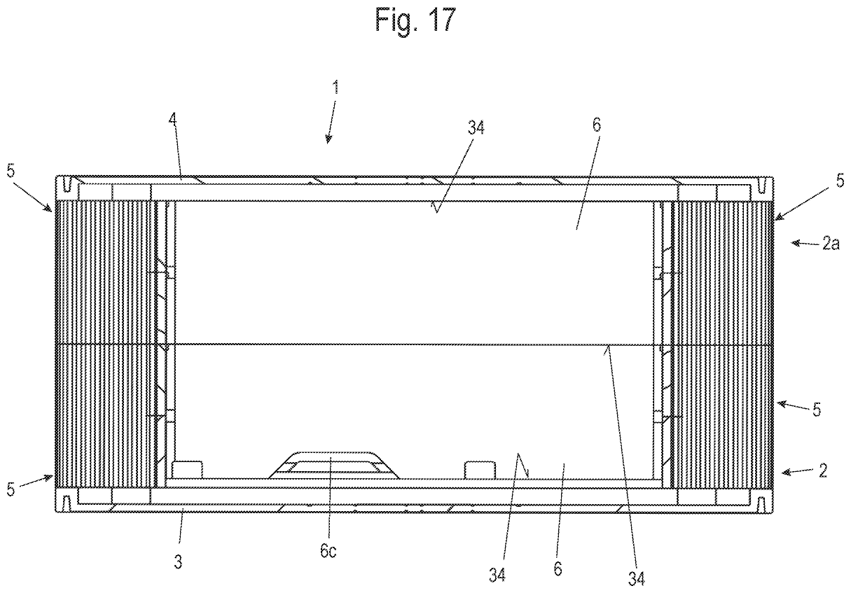

FIG. 17 is a sectional view of a variant of the housing 1. The section runs in a longitudinal direction of the housing 1 through its middle parallel to the side walls 6.

The housing 1 can be provided with one or more ventilation openings 34, e.g., ventilation slots, at various locations. Instead of the ventilation openings 34, or even in addition, heat sinks can also be employed.

Ventilation slots can also be arranged between the side walls 6 and the bottom cover 3 and the cover 4. Further ventilation measures for the interior space of the housing 1 can be provided by through-holes (circular, oval, rectangular, slot-shaped and the like) in the bottom cover 3 and the top cover 4, and also in the side walls 6, 6a and slide-in walls 8. This type of ventilation can obviously also be implemented subsequently by the user.

The invention is not restricted by the exemplary embodiment described above.

For example, it is conceivable for a large slide-in wall at the height of three slide-in walls 8 to be used instead of two or three individual slide-in walls 8, as shown in FIG. 4 for example.

The covers 3, 4 and/or the walls 6, 6a, 8 can also include several parts. For example, flaps can be provided on them.

What is claimed is:

1. A housing system for electrical and electronic components, comprising
a housing including side walls and slide-in walls and at least one cover, wherein said housing comprises at least one basic frame including said side walls and at least one corner pillar, said at least one corner pillar forming at least one interface for external mounts and internal mounts.

2. The housing system as defined in claim 1, wherein said at least one basic frame has four corner pillars which are firmly connected with said side walls.

3. The housing system as defined in claim 1, wherein said housing includes at least one supplemental frame with at least one corner pillar.

4. The housing system as defined in claim 3, wherein said at least one supplementary frame has four corner pillars, two corner pillars of which are firmly connected to said side walls.

5. The housing system as defined in claim 1, wherein said at least one corner pillar has an outer jacket configured as a partially hollow cylinder with a three-quarter circular cross-section, said outer jacket defining an interface for an external mount.

6. The housing system as defined in claim 5, and further comprising at least one external mount including at least one clamping section having a semicircular cross-section with an internal radius corresponding to an external radius of said outer jacket as an interface for external mounts of said at least one corner pillar.

7. The housing system as defined in claim 6, and further comprising an inner pillar containing a central through-opening arranged in said outer jacket of said at least one corner pillar.

8. The housing system as defined in claim 7, wherein said through-opening of said inner pillar is configured as an internal hexagonal cross-section.

9. The housing system as defined in claim 8, and further comprising a channel wall which extends along said inner pillar and contains a channel arranged on said inner pillar.

10. The housing system as defined in claim 9, wherein each side of said channel wall includes a holding section defined by a prolongation of said side wall attached to said corner pillar, said channel wall and a bar attached to said side wall, wherein said holding sections at each side of said channel wall form an insert receptacle as an interface for said internal mounts.

11. The housing system as defined in claim 10, wherein said insert receptacle furthermore includes a bar which is secured thereto in a longitudinal direction of said channel wall and which forms a separation of said two holding sections in the longitudinal direction.

12. The housing system as defined in claim 11, wherein said two holding sections are divided in a transverse direction by a crossbar and form two insert receptacles each of which opens towards an interior space of an associated frame, wherein an opening is defined by said holding section bars, said holding bar and said crossbar, and wherein said insert receptacle forms said interface for said internal mounts of said at least one corner pillar.

13. The housing system as defined in claim 12, and further comprising at least one internal mount having a holding device configured for form-fitting engagement and corresponding to a configuration of said insert receptacle as an interface for said internal mounts of said at least one corner pillar.

14. The housing system as defined in claim 13, wherein said holding device includes at least one of bar-shaped protrusions and prestressed spring bars which fix said holding device in said holding sections in a form-fitting manner and in a force-fitting manner by friction.

15. The housing system as defined in claim 8, wherein said housing is held together by securing elements arranged in said through-opening of said inner pillar of said at least one corner pillar.

16. The housing system as defined in claim 7, wherein said housing is held together by magnets which form magnetic closures.

17. The housing system as defined in claim 16, wherein said magnets of said magnetic closures are arranged in the entrances to said through-opening of said inner pillar of said at least one corner pillar and in receptacles in said covers.

18. The housing system as defined in claim 7, wherein said covers include pillar caps which enclose said corner pillars.
